(19) United States
(12) Patent Application Publication
(10) Pub. No.: US 2016/0329376 A1
(43) Pub. Date: Nov. 10, 2016

(54) LIGHT EMITTING DIODE PACKAGE

(71) Applicant: Samsung Electronics Co., Ltd., Suwon-si (KR)

(72) Inventor: Hyung Kun Kim, Suwon-si (KR)

(21) Appl. No.: 14/990,124

(22) Filed: Jan. 7, 2016

(30) Foreign Application Priority Data
May 4, 2015 (KR) 10-2015-0062721

(51) Int. Cl. H01L 27/15; H01L 33/64; H01L 33/62

(52) U.S. Cl. CPC H01L 27/156; H01L 33/62; H01L 33/644

(57) ABSTRACT

A light emitting diode (LED) package includes a package board having a first surface having a plurality of chip mounting regions and a second surface opposing the first surface, and including a plurality of first and second through electrodes disposed in the plurality of chip mounting regions, a plurality of LED chips disposed in the plurality of chip mounting regions of the first surface of the package board and each having one surface on which first and second electrodes are disposed, wherein the first and second electrodes are connected to the first and second through electrodes positioned in the chip mounting regions, and a connection electrode disposed on at least one of the first surface and the second surface of the package board, and connecting the first and second through electrodes.

### CROSS-REFERENCE TO RELATED APPLICATION

This application claims the priority and benefit of Korean Patent Application No. 10-2015-0062721 filed on May 4, 2015, with the Korean Intellectual Property Office, the disclosure of which is incorporated herein by reference.

### TECHNICAL FIELD

Inventive concepts relate to a light emitting diode package.

### BACKGROUND

A semiconductor light emitting device such as a light emitting diode (LED) is a device including a light emitting material, in which energy generated through electron-hole recombination in semiconductor junction is converted into light to be emitted therefrom. LEDs are commonly employed as light sources in illumination devices, display devices, and the like.

In particular, the development and employment of gallium nitride (GaN)-based LEDs have recently increased, and mobile backlights, vehicle turn signal lamps, camera flashes, and the like, using such gallium nitride-based LEDs, have been commercialized. As a result, the development of general illumination devices using LEDs has accelerated. Like the products to which they are applied, such as a backlight unit of a large TV, headlamps of a vehicle, a general illumination device, and the like, the purposes of light emitting devices are gradually moving from small portable products toward large-sized products having high output and high efficiency and the applications thereof have expanded in kind.

Light emitting diode packages providing an increased amount of light are in demand, and a method for reducing manufacturing costs and manufacturing time is may be advantageous for mass-producing light emitting device packages.

### SUMMARY

An aspect of inventive concepts may provide a light emitting diode package providing an increased light density.

An aspect of inventive concepts may also provide a light emitting diode package that can be manufactured through a simple manufacturing process at low manufacturing costs.

According to an aspect of inventive concepts, a light emitting diode (LED) package may include: a package board having a first surface having a plurality of chip mounting regions and a second surface opposing the first surface, and including a plurality of first and second through electrodes electrically connecting the first surface and the second surface and disposed in the plurality of chip mounting regions, a plurality of integral LED chips disposed in the plurality of chip mounting regions of the first surface of the package board and each having one surface on which first and second electrodes are disposed, wherein the first and second electrodes are connected to the first and second through electrodes positioned in the chip mounting regions, and a connection electrode disposed on at least one of the first surface and the second surface of the package board, and connecting the first and second through electrodes of adjacent chip mounting regions so that the plurality of LED chips are connected in series or in parallel.

In example embodiments in accordance with principles of inventive concepts an LED package may further include first and second pad electrodes disposed on the second surface of the package board and covering at least one first and second through electrodes.

In example embodiments in accordance with principles of inventive concepts first and second pad electrodes and the connection electrode may substantially have the same thickness and may be formed of a material having the same composition.

In example embodiments in accordance with principles of inventive concepts an LED package may further include an encapsulant disposed on the first surface of the package board to cover the plurality of LED chips.

In example embodiments in accordance with principles of inventive concepts a plurality of LED chips may each include a light emitting structure formed by stacking a first conductivity-type semiconductor layer, an active layer, and a second conductivity-type semiconductor layer, and the second conductivity-type semiconductor layer may provide the one surface on which the first and second electrodes are disposed, and the first electrode may include one or more conductive vias electrically insulated from the second conductivity-type semiconductor layer and the active layer and extending to a region of the first conductivity-type semiconductor layer.

In example embodiments in accordance with principles of inventive concepts a plurality of LED chips may be arranged in a plurality of rows and a plurality of columns on the first surface of the package board.

In example embodiments in accordance with principles of inventive concepts LED chips arranged in the same column, among the plurality of LED chips, may be connected in series.

In example embodiments in accordance with principles of inventive concepts LED chips arranged in the same row, among the plurality of LED chips, may be connected in parallel.

In example embodiments in accordance with principles of inventive concepts LED package may further include a heat sink attached to the second surface of the package board.

In example embodiments in accordance with principles of inventive concepts LED package may further include an insulating layer disposed between the heat sink and the package board.

In example embodiments in accordance with principles of inventive concepts a circuit board may be disposed in a partial region of a region in which the heat sink and the package board are in contact, and the circuit board may be electrically connected to at least two of the plurality of LED chips.

In example embodiments in accordance with principles of inventive concepts a package board may include a molding unit surrounding the plurality of first and second through electrodes.

According to another aspect of inventive concepts, a light emitting diode (LED) package may include: a package board having a first surface and a second surface opposing the first surface, a plurality of first and second through electrodes penetrating through the package board in a thickness direction, and a plurality of LED chips electrically connected to the plurality of first and second through electrodes and mounted on the first surface of the package board, wherein at least one of the first and second through electrodes electrically connected to any one of the plurality of LED chips is electrically connected to any one of the first and second through electrodes electrically connected to an LED chip adjacent thereto.

In example embodiments in accordance with principles of inventive concepts at least one of the first and second through electrodes electrically connected to any one of the plurality of LED chips and the any one of the first and second through electrodes electrically connected to the LED chip adjacent thereto may be electrically connected by the connection electrode disposed on the second surface of the package board.

In example embodiments in accordance with principles of inventive concepts an LED package further includes a wavelength conversion unit to convert the wavelength of light emitted by an LED chip.

In example embodiments in accordance with principles of inventive concepts an LED package includes a heat sink attached to the second surface of the package board.

In example embodiments in accordance with principles of inventive concepts an LED package includes an insulating layer disposed between the heat sink and the package board.

In example embodiments in accordance with principles of inventive concepts an LED package includes a circuit board disposed in a partial region of a region in which the heat sink and the package board are in contact, and the circuit board is electrically connected to supply power to all the LED chips without direct connection to all of them.

In example embodiments in accordance with principles of inventive concepts an LED package includes a package board, the package board includes a molding unit surrounding the plurality of first and second through electrodes.

In example embodiments in accordance with principles of inventive concepts, a light emitting diode package includes a package board having a first surface and a second surface opposing the first surface; a plurality of integral LED chips mounted on the first surface of the package board; and a connection electrode disposed on at least one surface of the package board to connect adjacent LED chips

### BRIEF DESCRIPTION OF DRAWINGS

The above and other aspects, features and advantages of inventive concepts will be more clearly understood from the following detailed description taken in conjunction with the accompanying drawings, in which:

FIG. 1 is a perspective view illustrating a light emitting diode (LED) package according to an example embodiment of inventive concepts;

FIG. 2 is a cross-sectional view of the LED package of FIG. 1, taken along line A-A′;

FIG. 3(a) is a top plan view illustrating the LED package of FIG. 1;

FIG. 3(b) is a circuit diagram of FIG. 3(a);

FIG. 4 is a side cross-sectional view illustrating another example of an LED chip that may be employed in an example embodiment of inventive concepts;

FIG. 5 is an example embodiment of inventive concepts;

FIGS. 6 through 14 are views schematically illustrating a process of manufacturing the LED package of FIG. 1;

FIGS. 15A through 15H are cross-sectional views schematically illustrating a process of manufacturing an LED package according to another example embodiment of inventive concepts;

FIG. 16 is an exploded perspective view schematically illustrating a bulb type lamp as a lighting device according to an example embodiment of inventive concepts;

FIG. 17 is an exploded perspective view schematically illustrating a bar type lamp as a lighting device according to an example embodiment of inventive concepts;

FIGS. 18A and 18B are views schematically illustrating a white light source module employable in a lighting device;

FIG. 19 is a CIE 1931 color space chromaticity diagram illustrating light emitted by a lighting device according to an example embodiment of inventive concepts;

FIG. 20 is a view schematically illustrating an indoor lighting control network system; and

FIG. 21 is a view illustrating an embodiment of a network system applied to an open space.

### DETAILED DESCRIPTION

Various example embodiments in accordance with principles of inventive concepts will now be described more fully with reference to the accompanying drawings in which some embodiments are shown. Inventive concepts may, however, be embodied in different forms and should not be construed as limited to the embodiments set forth herein. Rather, these embodiments are provided so that this disclosure is thorough and complete and fully conveys inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Additionally, when an embodiment can be implemented differently, functions or operations described in a particular block may occur in a different way from a flow described in the flowchart. For example, two consecutive blocks may be performed simultaneously, or the blocks may be performed in reverse according to related functions or operations.

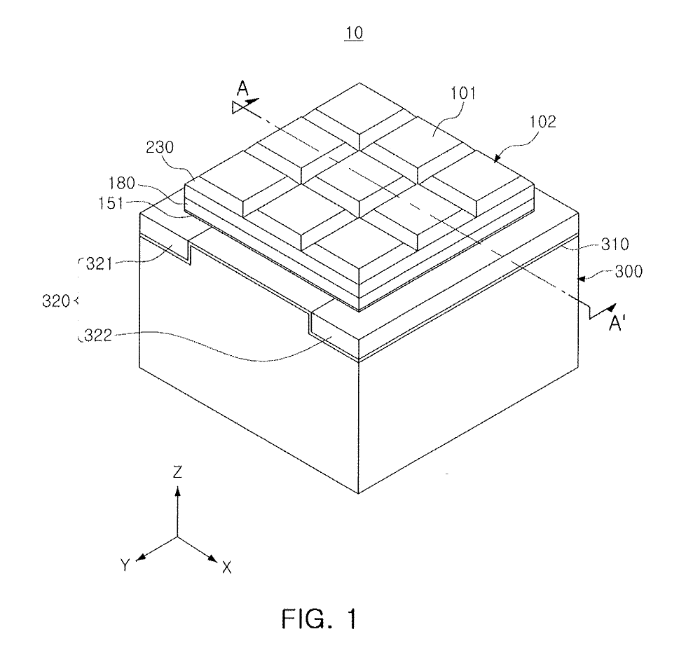

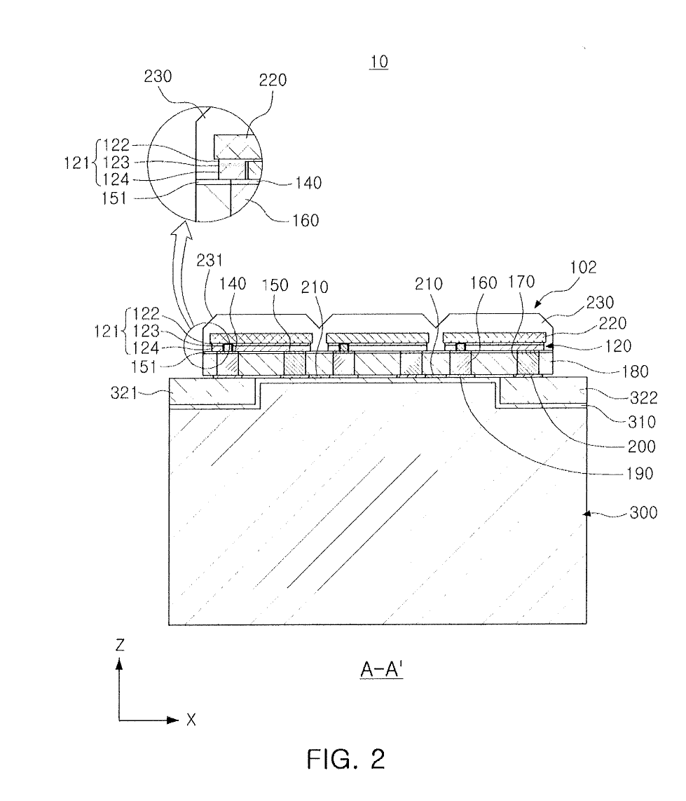

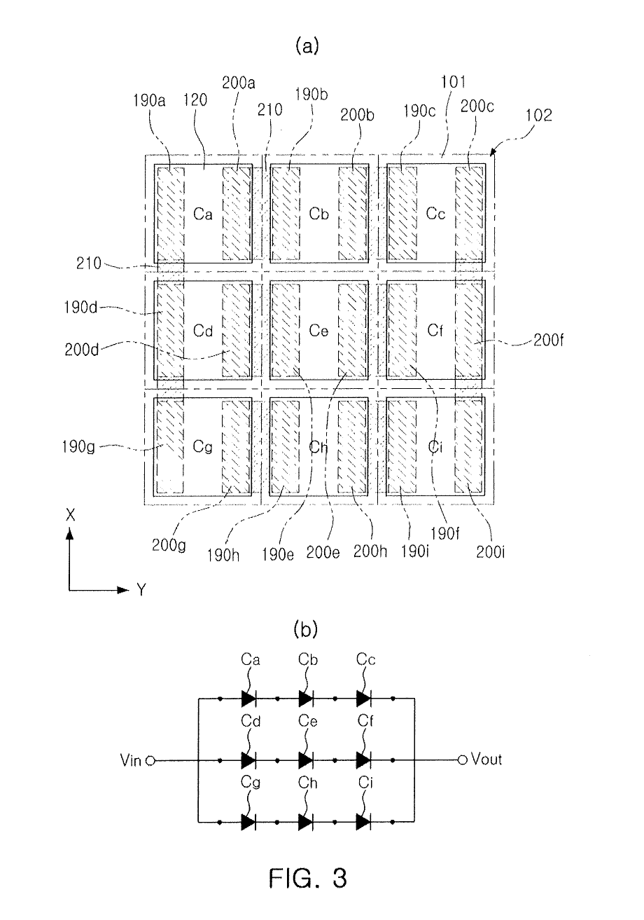

FIG. 1 is a perspective view illustrating a light emitting diode (LED) package according to an example embodiment in accordance with principles of inventive concepts, FIG. 2 is a cross-sectional view of the LED package of FIG. 1, taken along line A-A′, and FIG. 3(a) is a top plan view illustrating the LED package of FIG. 1.

Referring to FIGS. 1 and 2, an LED package 10 according to an example embodiment may include a package board 180 including a plurality of first and second through electrodes 160 and 170, a plurality of LED chips 120 mounted on the plurality of first and second through electrodes 160 and 170, and a connection electrode 210 connecting the plurality of LED chips 120 in series or in parallel.

The package board 180 includes the first and second through electrodes 160 and 170. First and second electrodes 140 and 150 may be electrically connected to the first and second through electrodes 160 and 170, respectively, by conductive connection units such as solder bumps, or the like. An insulating layer 151 may be disposed in regions of an upper surface of the package board 180, excluding regions in contact with the first and second electrodes 140 and 150.

The plurality of first and second through electrodes 160 and 170 penetrating through a first surface on which the LED chip 120 is mounted and a second surface opposing the first surface in a thickness direction may be formed in the package board 180. Additionally, a plurality of first and second pad electrodes 190 and 200 may be formed on the second surface of the package board 180 to which one end portion of each of the plurality of first and second through electrodes 160 and 170 are exposed to facilitate electrical connection of the package board 180. The package board 180 may be a board for manufacturing a so-called chip scale package (CSP), for example.

In example embodiments in accordance with principles of inventive concepts, the package board 180 may be formed of an organic resin material containing epoxy, triazine, silicone, or polyimide, and any other organic resin materials. The package board 180 may be formed by attaching the first and second through electrodes 160 and 170 to the LED chip 120 and molding the same with a resin, or the LED chip 120 may be separately manufactured and subsequently mounted.

In order to enhance heat dissipation characteristics and luminous efficiency, the package board 180 may be formed of ceramics having properties such as high heat resistance, excellent thermal conductivity, and high reflective efficiency, such as Al₂O₃ or AlN. However, materials of the package board 180 are not limited thereto, and various materials may be used in consideration of heat dissipation characteristics or the electrical connection relationship of the LED package 10.

In addition to the aforementioned resin or ceramic, a printed circuit board (PCB) or a lead frame may also be used as the package board 180 of example embodiments in accordance with principles of inventive concepts, for example.

The connection electrode 210 may be disposed in at least one of the plurality of first and second through electrodes 160 and 170 to electrically connect the plurality of first and second through electrodes 160 and 170 to first and second through electrodes 160 and 170 adjacent thereto so that the plurality of LED chips 120 mounted on the first and second through electrodes 160 and 170 may be connected in series and/or in parallel. Such connections will be described in greater detail in the discussion related to FIGS. 3(a) and 3(b). Hereinafter, for the purposes of description, a region of the LED package in which one LED chip 120 is mounted will be defined as a “unit device 101”, and a plurality of unit devices disposed to be adjacent to each other will be defined as a “unit device array 102”.

FIG. 3(a) is a top plan view illustrating the LED package of FIG. 1, in which the LED chips 120 are exposed by “removal of” wavelength conversion unit 220 and encapsulant 230 (illustrated in FIG. 2, for example, and to be described in greater detail hereinafter). FIG. 3(b) is a circuit diagram illustrating an electrical connection relationship of a plurality of LED chips 120 illustrated in FIG. 3(a).

At least one of first and second pad electrodes 190 and 200 directly connected to any one LED chip may be electrically connected to any one of first and second pad electrodes 190 and 200 directly connected to another LED chip adjacent thereto through the connection electrode 210.

That is, in accordance with principles of inventive concepts, an electrode pad (for example, 190b or 200b) associated with one LED chip Cb may be directly connected to an electrode pad (for example, 200a or 190c) associated with an adjacent LED chip Ca or Cc by direct connection through a connection electrode 210 formed on a surface of package board 180.

In example embodiments in accordance with principles of inventive concepts all the unit devices 101 in a device array 102 are integral to one another. That is, rather than separating unit devices 101 within a wafer, of LED devices, for example, from one another, in accordance with principles of inventive concepts, groups of unit devices, device arrays 102, are separated from one another in a wafer. Those larger-scale integrated devices, or device arrays 102, may be connected according to connection pads 210 for operation.

The first and second pad electrodes 190 and 200 may be disposed so that the LED chips 120 mounted on the package board 180 are arranged in a plurality of rows and columns. The disposition of the first and second pad electrodes 190 and 200 is not limited to a specific arrangement and may be modified to embodiments such as a lattice arrangement or a honeycomb arrangement, for example. In example embodiments in accordance with principles of inventive concepts, a case in which nine unit devices 101 forming three rows and three columns constitute a single unit device array 102 will be described as an example.

As illustrated in FIGS. 2 and 3(a), first and second pad electrodes 190 and 200 and the connection electrode 210 may be disposed on a first surface and/or a second surface of the package board 180 in order to electrically connect the plurality of first and second through electrodes 160 and 170. In example embodiments in which the first and second pad electrodes 190 and 200 are disposed in each of the plurality of first and second through electrodes 160 and 170, the connection electrode 210 may be disposed to be electrically connected to the first and second pad electrodes 190 and 200. In such embodiments case, the first and second pad electrodes 190 and 200 and the connection electrode 210 may be integrally manufactured through a single process. As a result, the first and second pad electrodes 190 and 200 and the connection electrode 210 may have substantially the same thickness and may be formed of a material having the same composition.

As illustrated in FIG. 3(a), the connection electrode 210 may be disposed so that the first and second pad electrodes 190 and 200 disposed within any one unit device 101 are directly electrically connected to the first and second pad electrodes 190 and 200 disposed to a unit device 101 adjacent thereto. In such embodiments, the LED chips 120 arranged in the unit device array 102 may form a serial and/or parallel circuit according to a disposition of the connection electrode 210 connected to the plurality of first and second pad electrodes 190a to 190i and 200a to 200i.

With the LED chips 120 included in the unit device array 102 referred to as Ca to Ci along the rows and columns, it can be seen that the LED chips Ca to Cc, Cd to Cf, and Cg to Ci forming the rows, constitute serial circuits and LED chips forming the columns constitute parallel circuits in the unit device array 102 as illustrated in the corresponding circuit diagram of FIG. 3(b).

In such embodiments, when power is applied only to Vin and Vout of FIG. 3(b), power may be applied to all the LED chips Ca to Ci of the unit device array 102. As a result, there is no need to individually apply power to each of the LED chips Ca to Ci, and circuit wirings (or circuit lines) for applying power to the LED package may be simplified. Additionally, because the single unit device array 102 is mounted, without having to separately mount each of the unit devices 101, the plurality of unit devices 101 may be simultaneously mounted, reducing manufacturing time to simplify a manufacturing process.

Each of the LED chips 120 may be mounted on the package board 180 and may include a light emitting structure 121 formed by stacking a first conductivity-type semiconductor layer 122, an active layer 123, and a second conductivity-type semiconductor layer 124. The first and second conductivity-type semiconductor layers 122 and 124 may be n-type and p-type semiconductor layers, respectively, and may be formed of a nitride semiconductor, for example. Accordingly, in example embodiments in accordance with principles of inventive concepts, the first and second conductivity-type semiconductor layers 122 and 124 may be understood to mean n-type and p-type semiconductor layers, respectively. The types of the semiconductor layers 122 and 124 are not limited thereto, and may be p-type and n-type semiconductor layers, respectively. The first and second conductivity-type semiconductor layers 122 and 124 may have an empirical formula as AlₓIn_{y}Ga_{(1-x-y)}N, where ≦x≦1, 0≦y<1, and 0≦x+y<1, and for example, materials such as GaN, AlGaN, and InGaN may correspond thereto.

The active layer 123 may be a layer for emitting ultraviolet light and/or visible light (having a wavelength ranging from about 350 nm to 680 nm) and may be configured as a doped and/or undoped nitride semiconductor layer having a single quantum well (SQW) structure of a multi-quantum well (MQW) structure. For example, the active layer 123 may have an MQW structure in which quantum barrier layers and quantum well layers of AlₓIn_{y}Ga_{(1-x-y)}N, where 0≦x<1, 0≦y<1, and 0≦x+y<1, are alternately stacked and have a predetermined band gap. Electrons and holes are recombined by quantum wells to emit light and the MQW structure, for example, an InGaN/GaN structure, may be used as such. The first and second conductivity-type semiconductor layers 122 and 124 and the active layer 123 may be formed using a crystal growth process such as metal organic chemical vapor deposition (MOCVD), molecular beam epitaxy (MBE), or hydride vapor phase epitaxy (HVPE).

As the LED chip 120, an LED chip having a so-called epi-up or a flip-chip structure in which first and second electrodes 140 and 150 are disposed in the same direction may be used. The LED chip 120 may further include a buffer layer, a superlattice layer, and/or an interlayer to reduce a crystal defect during a growth process of the semiconductor layers, for example.

The first and second electrodes 140 and 150 serve to apply power to the first and second conductivity-type semiconductor layers 122 and 124 and may be provided to be in ohmic-contact with the first and second conductivity-type semiconductor layers 122 and 124.

The first and second electrodes 140 and 150 may be formed of a conductive material having ohmic-contact and light reflecting properties with respect to the first and second conductivity-type semiconductor layers 122 and 124, and may have a single layer or multi-layer structure. For example, the first and second electrodes 140 and 150 may be formed by depositing one or more of materials such as gold (Au), silver (Ag), copper (Cu), zinc (Zn), aluminum (Al), indium (In), titanium (Ti), silicon (Si), germanium (Ge), tin (Sn), magnesium (Mg), tantalum (Ta), chromium (Cr), tungsten (W), ruthenium (Ru), rhodium (Rh), iridium (Ir), nickel (Ni), palladium (Pd), platinum (Pt), and a transparent conductive oxide (TCO). The first and second electrodes 140 and 150 may be disposed on a surface of the package board 180 on which the LED chip 120 is mounted.

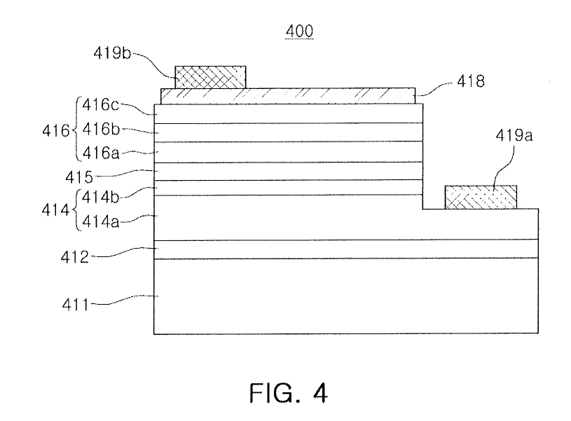

FIG. 4 is a side cross-sectional view illustrating another example of an LED chip that may be employed in an example embodiment in accordance with principles of inventive concepts.

An LED chip 400 illustrated in FIG. 4 includes a substrate 411, and a first conductivity-type semiconductor layer 414, an active layer 415, and a second conductivity-type semiconductor layer 416 sequentially disposed on the substrate 411. A buffer layer 412 may be disposed between the substrate 411 and the first conductivity-type semiconductor layer 414.

The substrate 411 may be an insulating substrate such as sapphire. However, the material of the substrate 411 is not limited thereto, and the substrate 411 may be a conductive substrate or a semiconductor substrate, as well as the insulating substrate. For example, the substrate 411 may be formed of SiC, Si, MgAl₂O₄, MgO, LiAlO₂, LiGaO₂, or GaN, as well as of sapphire.

The buffer layer 412 may be formed of InₓAl_{y}Ga_{1-x-y}N, where 0≦x≦1, 1≦y≦1, and 0≦x+y≦1. The buffer layer 412 may be used by combining a plurality of layers or by gradually changing a composition as necessary.

The first conductivity-type semiconductor layer 414 may be a nitride semiconductor satisfying n-type InₓAl_{y}Ga_{1-x-y}N, where 0≦x<1, 0≦y<1, and 0≦x+y<1, and an n-type impurity may be silicon (Si). For example, the first conductivity-type semiconductor layer 414 may include an n-type GaN.

In example embodiments in accordance with principles of inventive concepts, the first conductivity-type semiconductor layer 414 may include a first conductivity-type semiconductor contact layer 414a and a current spreading layer 414b. The impurity concentration of the first conductivity-type semiconductor contact layer 414a may range from 2×10¹⁸ cm⁻³ to 9×10¹⁹ cm⁻³, for example, and the thickness of the first conductivity-type semiconductor contact layer 414a may range from 1 μm to 5 μm.

The current spreading layer 414b may have a structure in which a plurality of InₓAl_{y}Ga_{(1-x-y)}N layers, where 0≦x, y≦1, and 0≦x+y≦1, having different compositions or different impurity contents are repeatedly stacked. For example, the current spreading layer 414b may be an n-type GaN layer having a thickness ranging from 1 nm to 500 nm and/or an n-type superlattice layer formed by repeatedly stacking two or more layers having different compositions formed of AlₓIn_{y}Ga_{z}N, where 0≦x, y, z≦1, excluding x=y=z=0). An impurity concentration of the current spreading layer 414b may range from 2×10¹⁸ cm⁻³ to 9×10¹⁹ cm⁻³. In example embodiments the current spreading layer 414b may further include an insulating material layer.

The second conductivity-type semiconductor layer 416 may be a nitride semiconductor layer satisfying p-type InₓAl_{y}Ga_{1-x-y}N, where 0≦x<1, 0≦y<1, and 0≦x+y<1), and a p-type impurity may be magnesium (Mg). For example, the second conductivity-type semiconductor layer 416 may be formed to have a single layer structure or may have a multi-layer structure having different compositions, as in this example embodiment. As illustrated in FIG. 4, the second conductivity-type semiconductor layer 416 may include an electron blocking layer (EBL) 416a, a p-type low-concentration GaN layer 416b, and a p-type high-concentration GaN layer 416c. For example, the electron blocking layer 416a may have a structure in which a plurality of InₓAl_{y}Ga_{(1-x-y)}N layers, where 0≦x≦1, 0≦y≦1, and ranging from 5 nm to 100 nm and having different compositions are stacked or may be a single layer formed of Al_{y}Ga_{(1-y)}N, where 0<y≦1. An energy band gap (Eg) of the electron blocking layer 416a may decrease in a direction away from the active layer 415. For example, an aluminum (Al) composition of the electron blocking layer 416a may decrease in a direction away from the active layer 415.

The active layer 415 may have a multi-quantum well (MQW) structure in which quantum well layers and quantum barrier layers are alternately stacked. For example, the quantum well layer and the quantum barrier layer may be formed of InₓAl_{y}Ga_{1-x-y}N, where 0≦x≦0, 1≦y≦1, and 0≦x+y≦1, having different compositions. In example embodiments, the quantum well layer may be formed of InₓGa₁₋ₓN, where 0<x≦1, and the quantum barrier layer may be formed of GAN or AlGaN. Thicknesses of the quantum well layer and of the quantum barrier layer may range from 1 nm to 50 nm. The active layer 415 may have a single quantum well structure and example embodiments are not limited to the multi-quantum well structure.

The LED chip 400 may include a first electrode 419b disposed on the first conductivity-type semiconductor layer 414 and an ohmic-contact layer 418 and a second electrode 419b sequentially disposed on the second conductivity-type semiconductor layer 416.

Although not limited thereto, the first electrode 419a may include a material such as Ag, Ni, Al, Cr, Rh, Pd, Ir, Ru, Mg, Zn, Pt, or Au and may have a structure including a single layer or two or more layers. A pad electrode layer may be further provided on the first electrode 419a. The pad electrode layer may be a layer including at least one of materials such as gold (Au), nickel (Ni), and tin (Sn).

The ohmic-contact layer 418 may be configured according to a chip structure. For example, in a case of a flip-chip structure, the ohmic-contact layer 418 may include a metal such as silver (Ag), gold (Au), or aluminum (Al) and a transparent conductive oxide such as indium tin oxide (ITO), zinc indium oxide (ZIO), or gallium indium oxide (GIO). In example embodiments in which a structure is disposed conversely, the ohmic contact layer 418 may be configured as a translucent electrode. The translucent electrode may be either a transparent conductive oxide layer or a nitride layer. For example, the translucent electrode may be at least one selected from among ITO, zinc-doped indium tin oxide (ZITO), ZIO, GIO, zinc tin oxide (ZTO), fluorine-doped tin oxide (FTO), aluminum-doped zinc oxide (AZO), gallium-doped zinc oxide (GZO), In₄Sn₃O₁₂, and Zn₍₁₋ₓ₎MgₓO (Zinc Magnesium Oxide, where 0≦x≦1). In example embodiments in accordance with principles of inventive concepts the ohmic-contact layer 418 may include graphene. The second electrode 419b may include at least one of Al, Au, Cr, Ni, Ti, and Sn.

Referring to FIG. 2, a wavelength conversion unit 220 may be disposed on an upper surface of the LED chip 120. The wavelength conversion unit 220 may be formed as a sheet having a predetermined thickness and may be a film formed by dispersing a material such as a phosphor in a semi-curable (B-stage) material which is in a semi-cured state at room temperature and changed in phase to be flowable when heated. Also, the wavelength conversion unit 220 may be formed by mixing a wavelength conversion material such as phosphor or quantum dots (QD) in a glass composition and sintering the mixture.

In detail, the semi-curable material may be B-stage silicone. In example embodiments in accordance with principles of inventive concepts, the wavelength conversion unit 220 may have a structure in which a single layer is stacked or may be formed as multiple layers. In a case in which the wavelength conversion unit 220 is formed as multiple layers, the multiple layers may include different types of phosphors, for example.

The wavelength conversion unit 220 may be formed by mixing a phosphor to a semi-cured resin material. For example, the wavelength conversion unit 220 may be a B-stage composite material formed by mixing a phosphor to a polymer binder formed of a resin, a curing agent, and a curing catalyst and semi-curing the mixture.

As the phosphor, garnet-based phosphors (YAG, TAG, LuAG), silicon-based phosphors, nitride-based phosphors, sulfide-based phosphors, or oxide-based phosphors may be used. The phosphor may be a single species or a plurality of species mixed at a predetermined ratio. In example embodiments in accordance with principles of inventive concepts, at least one red phosphor may be included.

Table 1 below shows phosphors that may be used in the wavelength conversion unit 220 by application fields. The phosphors may be employed when a light emitting structure emits blue light (wavelength ranging from 440 nm to 460 nm) or UV light (wavelength ranging from 380 nm to 440 nm).

TABLE 1

| Purpose | Phosphor |
|---|---|
| LED TV | β-SiAlON:Eu2⁺, (Ca, Sr)AlSiN₃:Eu²⁺, La₃Si₆N₁₁:Ce³⁺, |
| BLU | K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4), |
| | K₂TiF₆:Mn⁴⁺, NaYF₄:Mn⁴⁺, NaGdF₄:Mn⁴⁺, K₃SiF₇:Mn⁴⁺ |
| Lighting | Lu₃Al₅O₁₂:Ce³⁺, Ca-α-SiAlON:Eu²⁺, La₃Si₆N₁₁:Ce³⁺, |
| | (Ca, Sr)AlSiN₃:Eu²⁺, Y₃Al₅O₁₂:Ce³⁺, K₂SiF₆:Mn⁴⁺, |
| | SrLiAl₃N₄:Eu, Ln₄₋ₓ(Eu_{z}M_{1-z})ₓSi_{12-y}Al_{y}O_{3+x+y}N₁₈−x−y |
| | (0.5 ≦ x ≦ 3, 0 < z < 0.3, 0 < y ≦ 4), K₂TiF₆:Mn⁴⁺, |
| | NaYF₄:Mn⁴⁺, NaGdF₄:Mn⁴⁺, K₃SiF₇:Mn⁴⁺ |
| Side | Lu₃Al₅O₁₂:Ce³⁺, Ca-α-SiAlON:Eu²⁺, La₃Si₆N₁₁:Ce³⁺, |
| Viewing | (Ca, Sr)AlSiN₃:Eu²⁺, Y₃Al₅O₁₂:Ce³⁺, (Sr, Ba, Ca, |
| (Mobile | Mg)₂SiO₄:Eu²⁺, K₂SiF₆:Mn⁴⁺, SrLiAl₃N₄:Eu, |
| Device, | Ln₄₋ₓ(Eu_{z}M_{1-z})ₓSi_{12-y}Al_{y}O_{3+x+y}N_{18-x-y} (0.5 ≦ x ≦ 3, |
| Laptop | 0 < z < 0.3, 0 < y ≦ 4), K₂TiF₆:Mn⁴⁺, NaYF₄:Mn⁴⁺, |
| PC) | NaGdF₄:Mn⁴⁺, K₃SiF₇:Mn⁴⁺ |
| Electrical | Lu₃Al₅O₁₂:Ce³⁺, Ca-α-SiAlON:Eu²⁺, La₃Si₆N₁₁:Ce³⁺, |
| component | (Ca, Sr)AlSiN₃:Eu²⁺, Y₃Al₅O₁₂:Ce³⁺, K₂SiF₆:Mn⁴⁺, |
| (Headlamp, | SrLiAl₃N₄:Eu, Ln₄₋ₓ(Eu_{z}M_{1-z})ₓSi_{12-y}Al_{y}O_{3+x+y}N_{18-x-y} |
| etc.) | (0.5 ≦ x ≦ 3, 0 < z < 0.3, 0 < y ≦ 4), K₂TiF₆:Mn⁴⁺, |
| | NaYF₄:Mn⁴⁺, NaGdF₄:Mn⁴⁺, K₃SiF₇:Mn⁴⁺ |

Also, the wavelength conversion unit 220 may be formed of wavelength conversion materials such as quantum dots, and in example embodiments in accordance with principles of inventive concepts, the quantum dots may be used in place of phosphors or may be mixed with phosphors so as to be used.

As a resin used in the wavelength conversion unit 220, an epoxy resin or a silicone resin as an inorganic polymer, satisfying high adhesive properties, high light transmittance, high heat resistance, high light refractive index, and moisture tolerance, may be used. In order to secure high adhesive properties, a silane-based material, for example, may be employed as an additive promoting enhancement of adhesion.

The encapsulant 230 may be disposed on the first surface of the package board 180 to cover all of the plurality of LED chips 120 and the plurality of wavelength conversion units 220. The encapsulant 230 may encapsulate the LED chips 120 and the wavelength conversion units 220 to protect the LED chips 120 and the wavelength conversion units 220 from moisture and heat, and may adjust a surface shape to adjust a beam angle of light emitted from the LED chips 120. For example, as illustrated in FIG. 2, an upper surface of the encapsulant 230 may be formed to be flat substantially parallel to the wavelength conversion unit 220, and a plurality of sloped portions 231 may be formed in units of the unit devices 101 in at least one region of the encapsulant 230.

The encapsulant 230 may be formed of a light-transmissive material. For example, the encapsulant 230 may be formed of an insulating resin having translucency such as silicone, strained silicone, epoxy, urethane, oxetane, acryl, polycarbonate, polyimide, and a composition formed of combinations thereof. However, materials of the encapsulant 230 are not limited thereto and an inorganic material having excellent light resistance such as glass or silica gel may also be used.

As illustrated in FIGS. 1 and 2, in accordance with principles of inventive concepts the package board 180 may be disposed on a heat sink 300.

In example embodiments in accordance with principles of inventive concepts an insulating layer 310 is disposed on a surface in which the heat sink 300 and the package board 180 are in contact in order to prevent the first and second pad electrodes 190 and 200 of the package board 180 from being short-circuited by the heat sink 300 formed of a conductive material such as a metal.

A circuit board 320 applying power to each of the first and second pad electrodes 190 and 200 of the package board 180 may be disposed in a partial region of the heat sink 300. The circuit board 320 may include first and second circuit boards 321 and 322 respectively connected to at least one of first and second pad electrodes 190 and 200. The insulating layer 310 may be further disposed between the first and second circuit boards 321 and 322 and the heat sink 300 to prevent the first and second circuit boards 321 and 322 and the heat sink 300 from being short-circuited. In example embodiments in which the insulating layer 310 is disposed, power may be applied only to the first and second pad electrodes 190 and 200 disposed on the first and second circuit boards 321 and 322. Power applied thusly may be applied to all the LED chips 120 mounted on the package board 180 through the connection electrode 210.

As a result, even if power is not individually applied to each of the unit devices 101, power may be applied to each of the plurality of LED chips 120 forming the unit device array 102 through the connection electrode 210, and the first and second circuit boards 321 and 322 for applying power to the LED package 10 may be further simplified. In addition, because an area in which the first and second pad electrodes 190 and 200 and the heat sink 300 are in contact increases, heat dissipation may be enhanced.

In LED package 10 having the aforementioned configuration, because the wafer-level package board 180 may be isolated in units of the unit device array 102 including a plurality of unit devices 101, rather than being isolated in units of the unit device 101, the time required to separate devices may be reduced, compared to a situation in which the wafer-level package board 180 is isolated in units of the unit device 101 and, consequently, manufacturing time may be reduced.

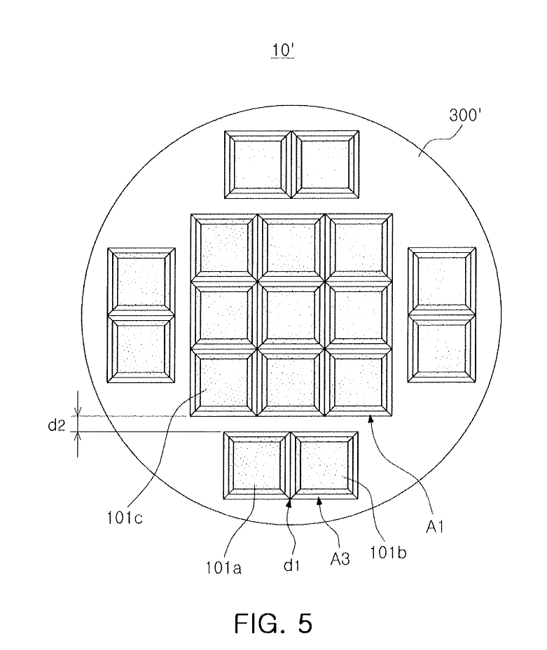

Additionally, in the LED package 10, the amount of light per unit area may be enhanced, compared to an existing chip-scale package. This advantage will be described in greater detail in the discussion related to FIG. 5, which illustrates an example embodiment of inventive concepts.

The LED package 10 described above is an example embodiment in which a single unit device array 102 is disposed on a single heat sink 300. In the example embodiment of FIG. 5, a plurality of unit device arrays A1 and A3 are disposed in LED module 10′, which is, in turn, mounted on a single heat sink 300′. In this example embodiment, a unit device array A1 in which unit devices 101c are arranged in three rows and three columns is disposed at the center of the heat sink 300′, and the unit device arrays A3 in one row and two columns or in two rows and one column are disposed around the unit device array A1, and as a result, compared to the example embodiment described above, the unit devices 101a, 101b, and 101c may be disposed in a shape nearly circular overall. Consequently, compared to the example embodiment described above, light irradiated to a light irradiation surface may have a nearly circular shape.

Referring to FIG. 5, in this example embodiment the unit devices 101a and 101b forming the unit device array A3 are in contact with each other without a gap d1 therebetween. Additionally, the unit device arrays A1 and A3 are spaced apart from one another by a predetermined gap d2. As a result, compared to a case in which all the unit devices are disposed to be isolated, a gap between the unit devices 101a, 101b, and 101c forming the unit device arrays A1 and A3 is removed (the unit devices 101a, 101b, and 101c forming the unit device arrays A1 and A3 are formed without a gap therebetween).

Because the gap present between the unit devices is removed, more unit devices 101 may be disposed within the same unit area, thereby increasing an amount of light emitted per unit area.

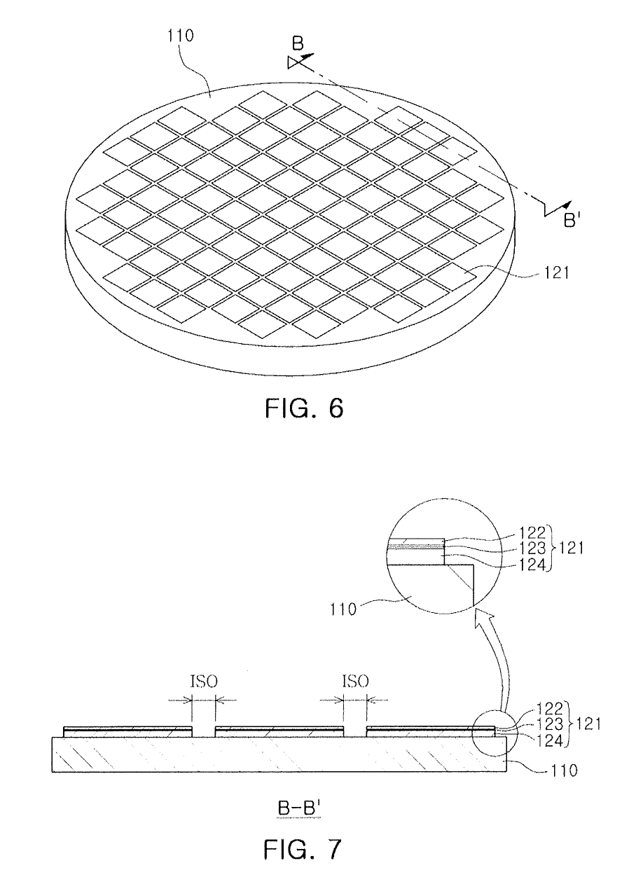

Hereinafter, a process of manufacturing an LED package according to an example embodiment will be described. FIGS. 6 through 14 are views schematically illustrating an example embodiment of a process of manufacturing an LED package in accordance with principles of inventive concepts, such as that of FIG. 1.

More particularly, FIG. 6 is a view illustrating a light emitting structure 121 disposed on a growth substrate 110, and FIG. 7 is a cross-sectional view taken along line B-B′ of FIG. 6.

First, the light emitting structure 121 including the first conductivity-type semiconductor layer 122, the active layer 123, and the second conductivity-type semiconductor layer 124 may be formed on the growth substrate 110. A region of the light emitting structure 121 may be etched to form an isolation region ISO in which the growth substrate 110 is exposed.

The growth substrate 110 may be provided as a semiconductor growth substrate, and may be formed of an insulating, a conductive, or a semiconductive material such as sapphire, SiC, MgAl₂O₄, MgO, LiAlO₂, LiGaO₂, or GaN, for example. Sapphire is a crystal having Hexa-Rhombo R3c symmetry, and has a lattice constant of 13,001 Å on a c-axis and a lattice constant of 4,758 Å on an a-axis. Sapphire has a C(0001) plane, an A(11-20) plane, and an R(1-102) plane. In this case, the C plane is mainly used as a nitride growth substrate because it facilitates the growth of a nitride thin film and is stable at high temperatures. When the growth substrate 110 is formed of silicon (Si), it may be more appropriate for increasing a diameter and is relatively low in price, facilitating mass-production. Although not shown, before the light emitting structure 121 is formed, a buffer layer, a superlattice layer, or an interlayer may be further formed on the growth substrate 110, for example.

The first and second conductivity-type semiconductor layers 122 and 124 may be formed of a nitride semiconductor, namely, semiconductor materials respectively doped with an n-type impurity and a p-type impurity having an empirical formula of AlₓIn_{y}Ga_{(1-x-y)}N, where 0≦x<1, 0≦y<1, and 0≦x+y<1, and the nitride semiconductor may be typically GaN, AlGaN, or InGaN. Silicon (Si), germanium (Ge), selenium (Se), tellurium (Te), and the like, may be used as the n-type impurity, and manganese (Mg), zinc (Zn), beryllium (Be), and the like, may be used as the p-type impurity. The first and second conductivity-type semiconductor layers 122 and 124 may be grown using a process such as metal organic chemical vapor deposition (MOCVD), hydride vapor phase epitaxy (HVPE), or molecular beam epitaxy (MBE), for example. In an example embodiment, the first and second conductivity-type semiconductor layers 122 and 124 may be formed of GaN and, in example embodiments in accordance with principles of inventive concepts, the first and second conductivity-type semiconductor layers 122 and 124 may be formed on the growth substrate 110 using silicon (Si) as described above.

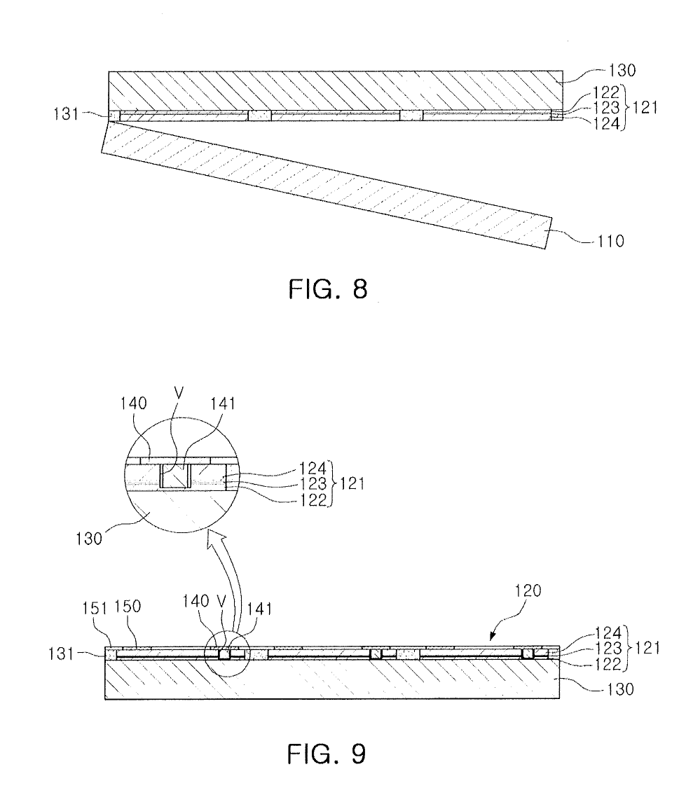

Thereafter, as illustrated in FIG. 8, a support substrate 130 is attached to the upper side of the light emitting structure 121 and the growth substrate 110 may be removed. Before the support substrate 130 is attached, an adhesive 131 may be applied to the light emitting structure 121. The support substrate 130 operates to prevent damage to the light emitting structure 121 during a follow-up manufacturing process. Various substrates may be attached as the support substrate 130, and in example embodiments in accordance with principles of inventive concepts, a silicon (Si) substrate may be attached.

After the support substrate 130 is attached, the growth substrate 110 may be separated from the light emitting structure 121. In example embodiments in which the growth substrate 110 is a transparent substrate such as sapphire, the growth substrate 110 may be separated from the light emitting structure 121 through a laser lift-off (LLO) process. A laser used during the LLO process may be any one of a 193 nm excimer laser, a 248 nm excimer laser, a 308 nm excimer laser, an Nd:YAG laser, an He—Ne laser, and an argon (Ar) ion laser, for example. When the growth substrate 110 is an opaque substrate such as silicon (Si), the growth substrate 110 may be removed through a physical method such as grinding, polishing, or lapping, for example.

Thereafter, as illustrated in FIG. 9, an insulating layer 151 may be formed to cover an exposed surface of the light emitting structure 121, and partial regions of the insulating layer 151 may be etched to expose a plurality of regions of the light emitting structure 121. Subsequently, a via V may be formed in a portion of the exposed regions, and a conductive ohmic-material may be deposited to form a via electrode 141. Additionally, a conductive ohmic-material may be deposited in the regions from which the insulating layer 151 has been removed, to form first and second electrodes 140 and 150. The first and second electrodes 140 and 150 may be transparent or reflective electrodes including at least one of Ag, Al, Ni, Cr, Cu, Au, Pd, Pt, Sn, W, Rh, Ir, Ru, Mg, Zn, a transparent conductive oxide (TCO), and a conductive material including these materials. Through this example process, the LED chip 120 may be manufactured, and during a follow-up process, a package board 180 may be disposed on the manufactured LED chip 120.

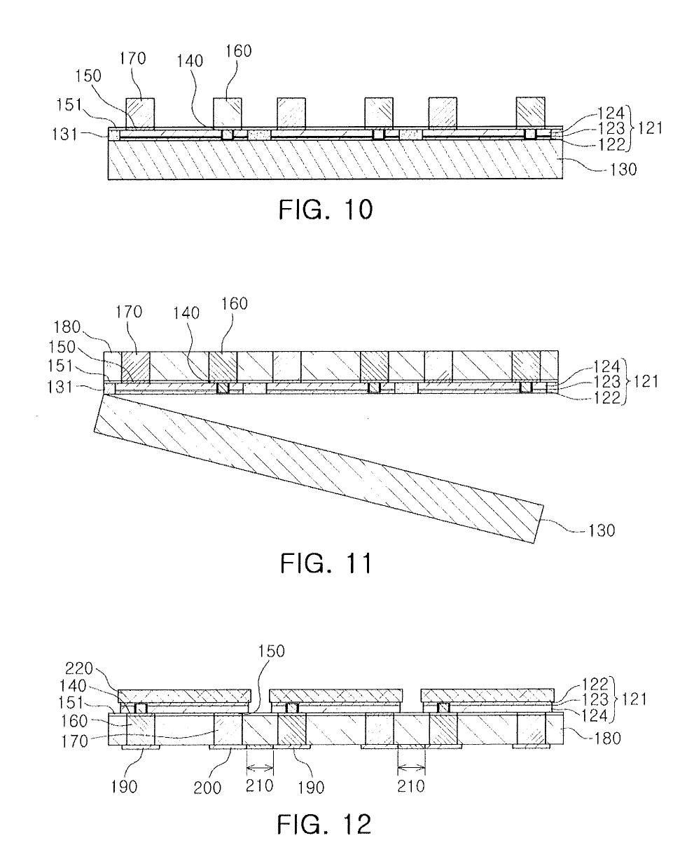

Thereafter, as illustrated in FIG. 10, first and second through electrodes 160 and 170 may be formed on the first and second electrodes 140 and 150 through plating. The first and second through electrodes 160 and 170 may be formed of copper (Cu), but the material of the first and second through electrodes 160 and 170 is not limited thereto, and the first and second through electrodes 160 and 170 may be formed of any other conductive material, for example.

Thereafter, as illustrated in FIG. 11, side surfaces of the first and second through electrodes 160 and 170 may be molded to form a package board 180. As a material used for the molding, a material such as a resin having a high Young's modulus sufficient to support the light emitting structure 121 and high thermal conductivity sufficient to dissipate heat generated by the light emitting structure 121 may be used. If example embodiments, a light-reflective material for reflecting light may be included in the material used for molding. As the light reflective material, TiO₂ or Al₂O₃ may be used, but the light reflective material is not limited thereto.

The forming of the package board 180 may include applying a molding material to cover upper surfaces of the first and second through electrodes 160 and 170 and exposing end portions of the first and second through electrodes 160 and 170 using a planarization method such as grinding. Thereafter, the support substrate 130 may be separated from the light emitting structure 121. In example embodiments in accordance with principles of inventive concepts, the support substrate 130 may be separated through the LLO process described above, or may also be removed through a physical method such as grinding, polishing, or lapping, for example.

Thereafter, as illustrated in FIG. 12, a conductive ohmic-material may be deposited on the exposed end portions of the first and second through electrodes 160 and 170 to form first and second pad electrodes 190 and 200 and a connection electrode 210. The first and second pad electrodes 190 and 200 and the connection electrode 210 may be deposited through separate processes or may be formed as an integrated single layer through a single process. Additionally, a process of forming a wavelength conversion unit 220 on the light emitting structure 121 may be performed. The wavelength conversion unit 220 may be formed of various wavelength conversion materials such as phosphor or quantum dots, for example.

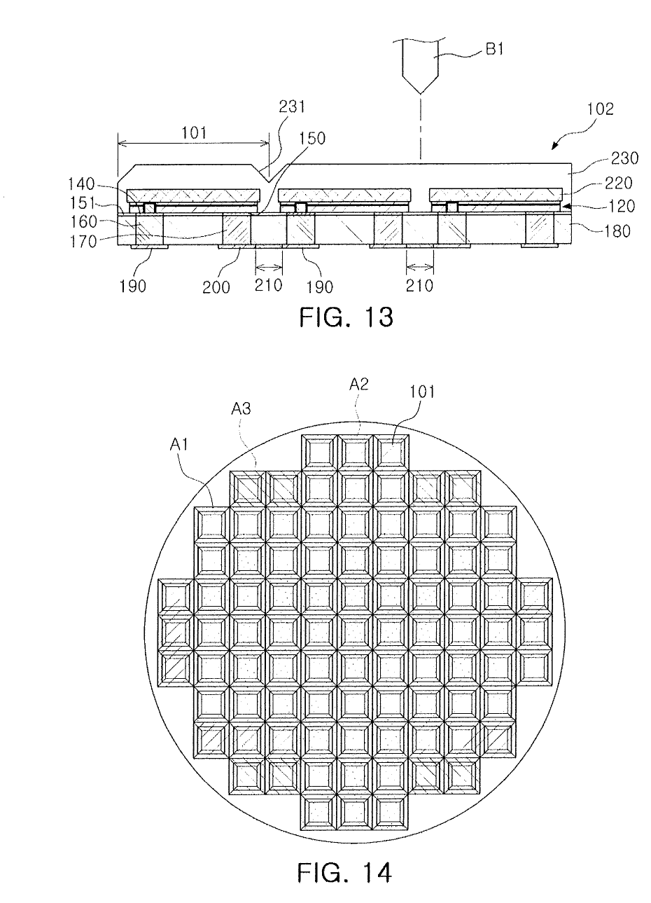

Thereafter, as illustrated in FIG. 13, an encapsulant 230 may be formed to cover the wavelength conversion unit 220 and the LED chip 120. A sloped portion 231 may be formed on an upper surface of the encapsulant 230 using a blade B1 in units of a unit device 101.

Thereafter, as illustrated in FIG. 14, a process of finally cutting the resultant structure into unit device arrays A1, A2, and A3 may be performed. The cutting process may be performed in such a manner that an adhesive tape is attached to the resultant structure and subsequently separated into individual packages through a blade cutting method.

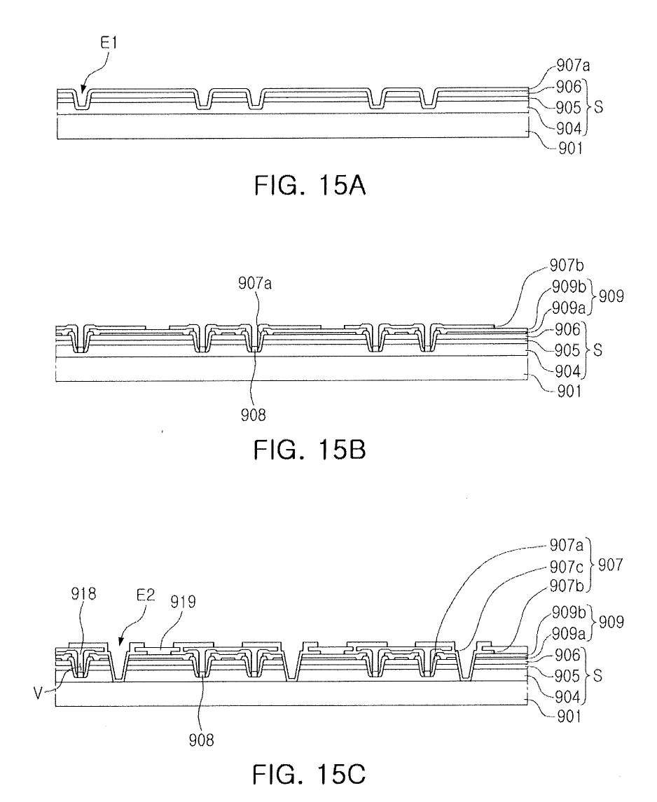

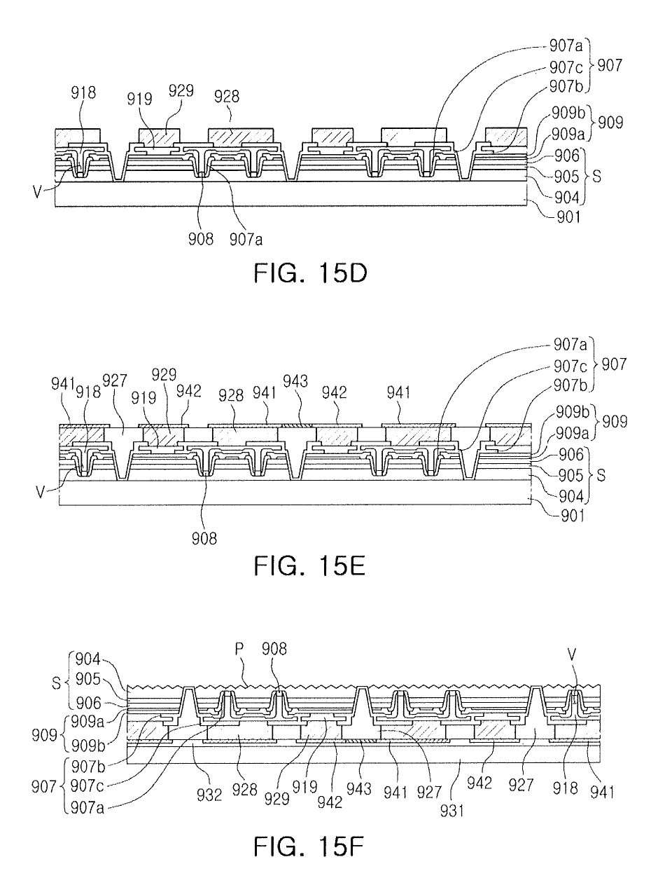

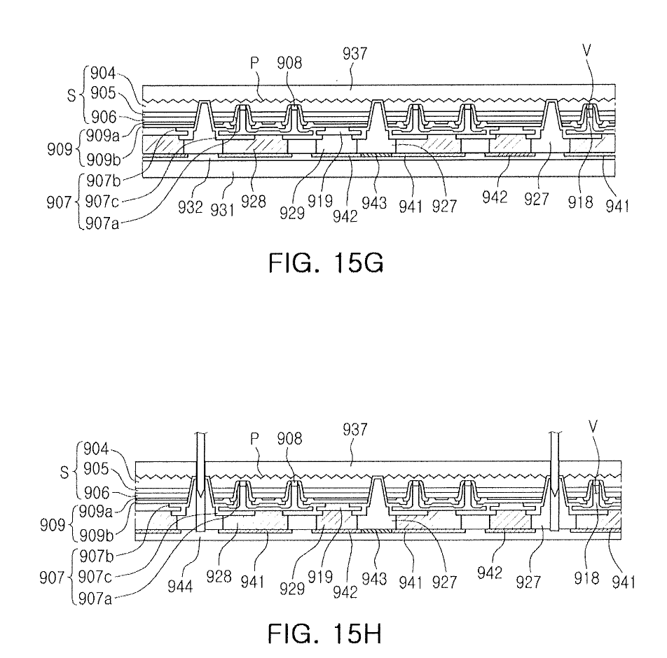

FIGS. 15A through 15H are cross-sectional views schematically illustrating a process of manufacturing an LED package according to another example embodiment of inventive concepts.

As illustrated in FIG. 15A, a light emitting structure S is formed in a wafer level on a substrate 901. The light emitting structure S may be formed by sequentially forming a first conductivity-type semiconductor layer 904, an active layer 905, and a second conductivity-type semiconductor layer 906. The substrate 901 may be a silicon (Si) substrate, but the type of the substrate 901 is not limited thereto.

Thereafter, a mesa etching region E1 may be formed in the light emitting structure S so that a portion of the first conductivity-type semiconductor layer 904 is exposed, and a first insulating layer 907a may be subsequently deposited. One mesa, or a plurality of mesas, may be formed per LED package through the etching process.

As illustrated in FIG. 15B, a portion of the first insulating layer 907a is etched, and a conductive ohmic-material is subsequently deposited to form first and second electrode units 908 and 909. The second electrode unit 909 may include a contact electrode layer 909a and a bonding electrode layer 909b.

Thereafter, a second insulating layer 907b may be formed on the first insulating layer 907a and the first and second electrode units 908 and 909, and portions of the first and second electrode units 908 and 909 may be subsequently exposed through etching.

The first and second electrode units 908 and 909 may be reflective and/or transmissive electrodes including at least one of Ag, Al, Ni, Cr, Cu, Au, Pd, Pt, Sn, W, Rh, Ir, Ru, Mg, Zn, and TCO, and an alloy material including these elements.

Referring to FIG. 15C, first and second pads 918 and 919 may be formed on the first and second electrode units 908 and 909. The first and second pads 918 and 919 may be electrically connected to the first and second electrode units 908 and 909, respectively.

A portion of the second pad 918 may form a conductive via V electrically connected to the first conductivity-type semiconductor layer 904. The conductive via V may be appropriately adjusted in number, shape, pitch, and a contact diameter (or a contact area) with respect to the first conductivity-type semiconductor layer 904 so that contact resistance is reduced, and may be arranged in various forms in rows and columns to improve current flow. The number and contact area of the conductive via V may be adjusted so that an area in which the conductive via V and the first conductivity-type semiconductor layer 904 are in contact ranges from 0.1% to 20% of a planar area of the light emitting structure S. For example, the area in which the conductive via V and the first conductivity-type semiconductor layer 904 are in contact may range from 0.5% to 15%, and further, may range from 1% to 10%. When the area is smaller than 0.1%, current dispersion may not be uniform, degrading light emitting characteristics, and when the electrode area increases to above 20%, a light emitting area is relatively reduced, reducing light emitting characteristics and luminance.

A radius of the conductive via V of the region in contact with the first conductivity-type semiconductor layer 904 may range from 1 μm to 50 μm, for example, and the number of conductive vias V may range from 1 to 48000 according to widths of the light emitting structure. Although varied according to the widths of the light emitting structure, the conductive via V may range in number from 2 to 45000, further, from 5 to 40000, and further, from 10 to 35000. A distance between the conductive vias V may range from 10 μm to 1000 μm, forming a lattice structure having rows and columns. For example, it may range from 50 μm to 700 μm, further, from 100 μm to 500 μm, and further, from 150 μm to 400 μm.

When the distance between the conductive vias V is less than 10 μm, the number of conductive vias V may increase to relatively reduce a light emitting area, degrading luminous efficiency, and when the distance therebetween is greater than 1000 μm, it may be difficult to spread current, thereby degrading luminous efficiency. A depth of the conductive via V may differ according to thicknesses of the second conductivity-type semiconductor layer 906 and the active layer 905, and may range from 0.1 μm to 5.0 μm, for example.

Thereafter, as illustrated in FIG. 15C, an isolation process may be performed to separate the light emitting structure into individual chip units. The isolation process may include forming an isolation region E2 using a blade, but without being limited thereto; any method may be used as long as it can cut the light emitting structure S without cutting the substrate 901. Through the aforementioned process, the light emitting structures S are separated into individual chips and supported on the substrate 901. The light emitting structure S obtained through the separation process may have a trapezoid shape in which an upper portion thereof is narrower than a lower portion thereof, and thus, sloped surfaces may be formed on the side surfaces of the light emitting structure S.

Thereafter, a third insulating layer 907c may be formed on the sloped surfaces of the light emitting structure S, the first and second pads 918 and 919, and the second insulating layer 907b, and thereafter, portions of the first and second pads 918 and 919 may be exposed. The third insulating layer 907c may provide passivation 907 together with the first and second insulating layers 907a and 907b remaining after being formed in a previous process.

Referring to FIG. 15D, first and second through electrodes 928 and 929 may be formed on the first and second pads 918 and 919. The first and second through electrodes 928 and 929 may be formed of copper (Cu), for example, but the material of the first and second through electrodes 928 and 929 is not limited thereto, and the first and second through electrodes 928 and 929 may be formed of any of a variety of conductive materials.

Referring to FIG. 15E, a side surface molding unit 927 formation process may be performed to fill gaps between the first and second through electrodes 928 and 929 and between the first and second through electrodes 928 and 929 and first and second through electrodes 928 and 929 of other light emitting structures S.

When the side surface molding unit 927 formation process is performed, a molding material having a high Young's modulus sufficient to support the light emitting structure S and high thermal conductivity sufficient to dissipate heat generated by the light emitting structure S may be used. Additionally, the side surface molding unit 927 may include a light reflective material for reflecting light downwardly. As the light reflective material, TiO₂ or Al₂O₃ may be used, for example, but the material is not limited thereto.

The side surface molding unit 927 formation process may include applying an encapsulation material to cover upper surfaces of the first and second through electrodes 928 and 929 and exposing end portions of the first and second through electrodes 928 and 929 using a planarization process such as grinding, or the like.

Thereafter, first and second pad electrodes 941 and 942 and a connection electrode 943 may be formed on the exposed end portions of the first and second through electrodes 928 and 929. The first and second pad electrodes 941 and 942 and the connection electrode 943 may be formed of a material having the same composition as that of a material of the first and second through electrodes 928 and 929, for example. In example embodiments in accordance with principles of inventive concepts, first and second pad electrodes 941 and 942 and the connection electrode 943 may be separately manufactured or may be manufactured through a single process. Because the disposition of the connection electrode 943 is the same as that of the former example embodiment described above, detailed descriptions thereof will not be repeated here, in order to avoid redundancy.

Thereafter, as illustrated in FIG. 15F, a process of removing the substrate 901 may be performed. During this process, a support substrate 931 may be temporarily bonded to a surface on which the first and second pad electrodes 941 and 942 and the connection electrode 943 are disposed. In order to bond the support substrate 931, a bonding material 932 such as a UV-cured material may be used. Thereafter, the substrate 901 may be removed through a method such as grinding or LLO. In example embodiments, a process of forming a texture P on a portion of the first conductivity-type semiconductor layer 904 may be performed in order to increase light emitting efficiency. In example embodiments, the process of removing the substrate 901 may be omitted.

Thereafter, as illustrated in FIG. 15G, a process of forming a wavelength conversion unit 937 on the light emitting structure S may be performed. The wavelength conversion unit 937 may be formed of various wavelength conversion materials such as phosphor and quantum dots. In example embodiments in accordance with principles of inventive concepts, various optical structures such as an optical lens may be used. In the structure in which the substrate 901 has not been removed illustrated in FIG. 15E, the wavelength conversion unit 937 may be formed on the substrate 901.

Thereafter, as illustrated in FIG. 15H, finally, a process of cutting the light emitting structure into individual packages may be performed. For example, the cutting process may be performed in such a manner that, after the support substrate 931 is removed, an adhesive tape is attached to the resultant structure and subsequently separated into individual packages through a blade cutting method.

A chip scale package obtained through the aforementioned process has substantially the same package size as that of a semiconductor light emitting device (i.e., the LED chip), and, as a result, a large amount of light may be obtained per unit area. Additionally, because all the processes are performed at the wafer level, a process in accordance with principles of inventive concepts is advantageously suited for mass-production, and the wavelength conversion material such as a phosphor and the optical structure such as a lens may be integrally manufactured together with the LED chip.

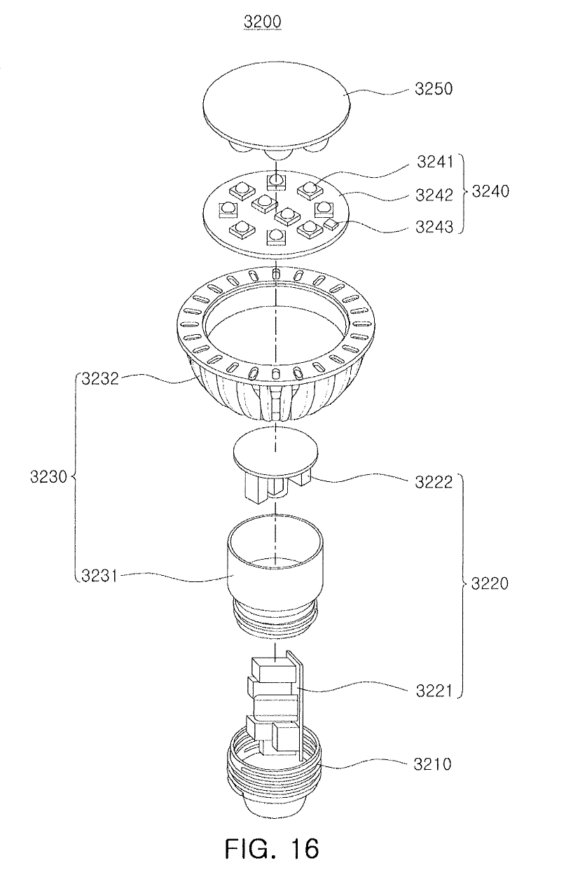

FIG. 16 is an exploded perspective view schematically illustrating a bulb-type lamp as a lighting device according to an example embodiment in accordance with principles of inventive concepts.

In detail, a lighting device 3200 may include a socket 3120, a power source unit 3220, a heat dissipation unit 3230, a light source module 3240, and an optical unit 3250. According to an example embodiment, the light source module 3240 may include a light emitting device array, and the power source unit 3220 may include a light emitting device driving unit.

The socket 3210 may be configured to be replaced with an existing lighting device. Power supplied to the lighting device 3200 may be applied through the socket 3210. As illustrated, the power source unit 3220 may include a first power source unit 3221 and a second power source unit 3222. The first power source unit 3221 and the second power source unit 3222 may be coupled to form the power source unit 3220. The heat dissipation unit 3230 may include an internal heat dissipation unit 3231 and an external heat dissipation unit 3232. The internal heat dissipation unit 3231 may be directly connected to the light source module 3240 and/or the power source unit 3220 to transmit heat to the external heat dissipation unit 3232. The optical unit 3250 may include an internal optical unit (not shown) and an external optical unit (not shown) and may be configured to evenly distribute light emitted from the light source module 3240.

In example embodiments in accordance with principles of inventive concepts, light source module 3240 may emit light to the optical unit 3250 upon receiving power from the power source unit 3220. The light source module 3240 may include one or more light emitting devices 3241, a circuit board 3242, and a controller 3243. The controller 3243 may store driving information for the light emitting devices 3241.

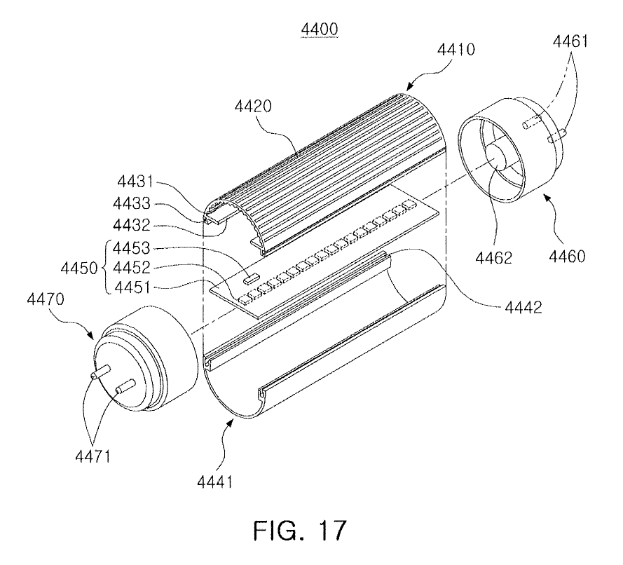

FIG. 17 is an exploded perspective view schematically illustrating a bar type lamp as a lighting device according to an example embodiment in accordance with principles of inventive concepts.

In this example embodiment, a lighting device 4400 includes a heat dissipation member 4410, a cover 4441, a light source module 4450, a first socket 4460, and a second socket 4470. A plurality of heat dissipation fins 4420 and 4431 may be formed in a concavo-convex pattern on an internal or/and external surface of the heat dissipation member 4410, and the heat dissipation fins 4420 and 4431 may be designed to have various shapes and intervals (spaces) therebetween. A support 4432 having a protrusion shape may be formed on an inner side of the heat dissipation member 4410. The light source module 4450 may be fixed to the support 4432. Stoppage protrusions 4433 may be formed on both ends of the heat dissipation member 4410.

Stoppage recesses 4442 may be formed in the cover 4441, and the stoppage protrusions 4433 of the heat dissipation member 4410 may be coupled to the stoppage recesses 4442 in a hook-coupling manner. The positions of the stoppage recesses 4442 and the stoppage protrusions 4433 may be interchanged.

The light source module 4450 may include a light emitting device array in accordance with principles of inventive concepts. The light source module 4450 may include a PCB 4451, a light source 4452, and a controller 4453. As described above, the controller 4453 may store driving information for the light source 4452. Circuit wirings are formed on the PCB 4451 to operate the light source 4452. Components for operating the light source 4452 may also be provided.

The first and second sockets 4460 and 4470, a pair of sockets, may be coupled to both ends of the cylindrical cover unit including the heat dissipation member 4410 and the cover 4441. For example, the first socket 4460 may include electrode terminals 4461 and a power source device 4462, and dummy terminals 4471 may be disposed on the second socket 4470. An optical sensor and/or a communications module may be installed in either the first socket 4460 or the second socket 4470. For example, the optical sensor and/or the communications module may be installed in the second socket 4470 in which the dummy terminals 4471 are disposed. In another example in accordance with principles of inventive concepts, the optical sensor and/or the communications module may be installed in the first socket 4460 in which the electrode terminals 4461 are disposed.

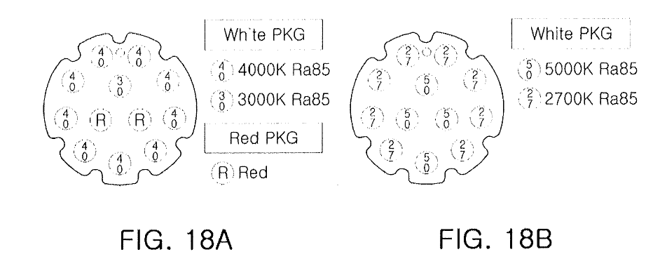

FIGS. 18(A) and 18(B) are views schematically illustrating a white light source module employable in a lighting device in accordance with principles of inventive concepts.

Light source modules illustrated in FIGS. 18(a) and 18(b) may include a plurality of light emitting device packages mounted on a circuit board. A plurality of light emitting device packages mounted on a single light source module may be configured as homogenous packages generating light having the same wavelength, or as in example embodiments in accordance with principles of inventive concepts, a plurality of light emitting device packages mounted on a single light source module may be configured as heterogeneous packages generating light having different wavelengths.

Referring to FIG. 18(A), an example embodiment of a white light source module may be configured by combining white light emitting device packages 40 and 30 respectively having color temperatures of 4000K and 3000K and a red light emitting device package ( ). The white light source module may provide white light having a color temperature that may be adjusted to range from 3000K to 4000K and having a color rendering index (CRI) Ra ranging from 85 to 100.

In another example embodiment in accordance with principles of inventive concepts, a white light source module may include only white light emitting device packages in which a portion of the packages may have white light having a different color temperature.

Referring to (B) of FIG. 18, an example embodiment of a white light source module includes only white light emitting device packages, and some of the packages may have white light having a different color temperature. For example, as illustrated in FIG. 18(b), a white light emitting device package 27 having a color temperature of 2700K and a white light emitting device package 50 having a color temperature of 5000K may be combined to provide white light having a color temperature that may be adjusted to range from 2700K to 5000K and having a CRI Ra ranging from 85 to 99. In example embodiments in accordance with principles of inventive concepts, the number of light emitting device packages of each color temperature may vary depending on a basically set color temperature value. For example, in a case of a lighting device in which a basically set value is a color temperature of about 4000K, the number of packages corresponding to 4000K may be greater than that of a color temperature of 3000K or the number of red light emitting device packages.

In this manner, the heterogeneous light emitting device packages are configured to include at least one of a light emitting device emitting white light by combining yellow, green, red, or orange phosphor to a blue light emitting device and a purple, blue, green, red, or infrared light emitting device, whereby a color temperature and CRI of white light may be adjusted. In example embodiments in accordance with principles of inventive concepts, white light source module described above may be used as the light source module 3240 of the bulb-type lighting device (“3200” of FIG. 16).

In a single light emitting device package in accordance with principles of inventive concepts, light having a desired color may be determined according to wavelengths of an LED chip as a light emitting device and types and mixing ratios of phosphors, and in a case of white light, a color temperature and a CRI may be adjusted.

For example, in example embodiments in which an LED chip emits blue light, a light emitting device package including at least one of yellow, green, and red phosphors may emit white light having various color temperatures according to mixing ratios of phosphors. In other example embodiments, a light emitting device package in which a green or red phosphor is applied to a blue LED chip may emit green or red light. In this manner, a color temperature or a CRI of white light may be adjusted by combining a light emitting device package emitting white light and a light emitting device package emitting green or red light. Additionally, at least one of light emitting devices emitting purple, blue, green, red, or infrared light may be included.

In example embodiments, the lighting device may control a color rendering index (CRI) to range from the level of light emitted by a sodium lamp to the level of sunlight, and may control a color temperature ranging from 2000K to 20000K to generate various levels of white light. In example embodiments in accordance with principles of inventive concepts, the lighting device may generate visible light having purple, blue, green, red, orange colors, or infrared light to adjust an illumination color according to a surrounding atmosphere or mood. Additionally, the lighting device may generate light having a wavelength stimulating plant growth.

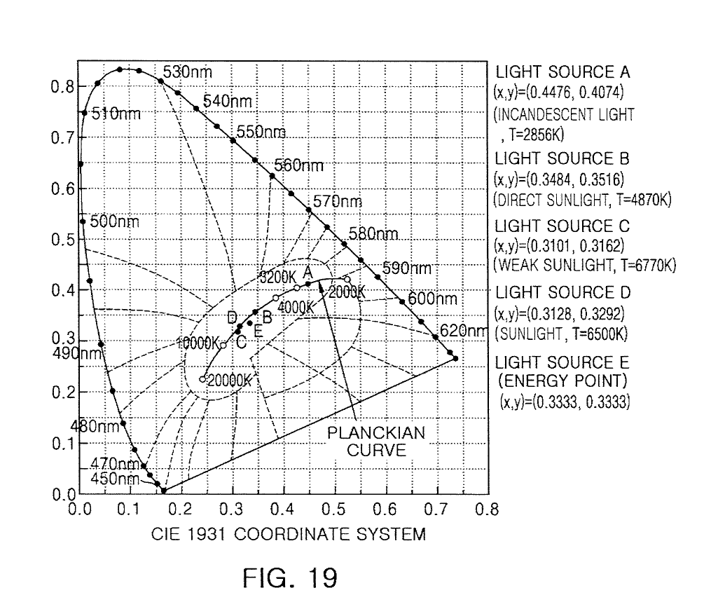

White light generated by combining yellow, green, and red phosphors to a blue light emitting device and/or by combining green and red light emitting devices thereto may have two or more peak wavelengths, and may be positioned in a segment linking (x, y) coordinates (0.4476, 0.4074), (0.3484, 0.3516), (0.3101, 0.3162), (0.3128, 0.3292), (0.3333, 0.3333) of the CIE 1931 chromaticity diagram as illustrated in FIG. 19. Alternatively, white light may be positioned in a region surrounded by a spectrum of black body radiation and the segment. A color temperature of white light corresponds to a range from about 2000K to about 20000K.

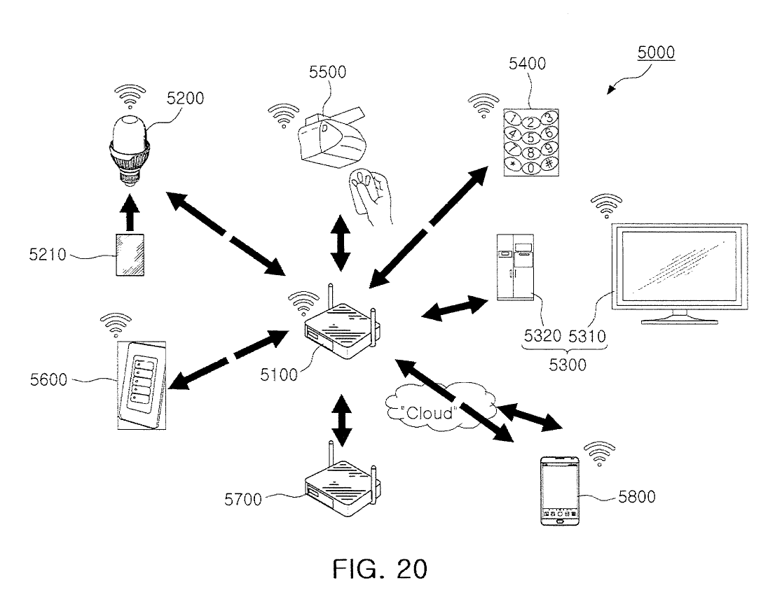

FIG. 20 is a view schematically illustrating an indoor lighting control network system in accordance with principles of inventive concepts.

A network system 5000 may be a complex smart lighting-network system combining lighting technology using a light emitting device such as an LED, or the like, Internet of things (IoT) technology, wireless communications technology, and the like. The network system 5000 may be realized using various lighting devices and wired/wireless communications devices, and may be realized by a sensor, a controller, a communications unit, software for network control and maintenance, and the like.

The network system 5000 may also be applied to an open space such as a park or a street, as well as to a closed space defined within a building such as a house or an office. The network system 5000 may be realized on the basis of the IoT environment in order to collect and process a variety of information and provide the same to users. In example embodiments in accordance with principles of inventive concepts, an LED lamp 5200 included in the network system 5000 may serve to check and control operational states of other devices 5300 to 5800 included in the IoT environment on the basis of a function such as visible light communications, or the like, of the LED lamp 5200, as well as receiving information regarding a surrounding environment from a gateway 5100 and controlling lighting of the LED lamp 5200 itself.

Referring to FIG. 20, the network system 5000 may include the gateway 5100 processing data transmitted and received according to different communications protocols, the LED lamp 5200 connected to be available for communicating with the gateway 5100 and including an LED light emitting device, and a plurality of devices 5300 to 5800 connected to be available for communicating with the gateway 5100 according to various wireless communications schemes. In order to realize the network system 5000 on the basis of the IoT environment, each of the devices 5300 to 5800, as well as the LED lamp 5200, may include at least one communications module. In an example embodiment, the LED lamp 5200 may be connected to be available for communicating with the gateway 5100 according to wireless communication protocols such as Wi-Fi, ZigBee, or Li-Fi, and to this end, the LED lamp 5200 may include at least one communications module 5210 for a lamp, for example.

As mentioned above, the network system 5000 may be applied to an open space such as a park or a street, as well as to a closed space such as a house or an office. When the network system 5000 is applied to a house, the plurality of devices 5300 to 5800 included in the network system and connected to be available for communicating with the gateway 5100 on the basis of the IoT technology may include a home appliance 5300 such as a television 5310 or a refrigerator 5320, a digital door lock 5400, a garage door lock 5500, a light switch 5600 installed on a wall, or the like, a router 5700 for relaying a wireless communication network, and a mobile device 5800 such as a smartphone, a tablet, or a laptop computer, for example.

In the network system 5000, the LED lamp 5200 may check operational states of various devices 5300 to 5800 using the wireless communications network (ZigBee, Wi-Fi, LI-Fi, etc.) installed in a household or may automatically control illumination of the LED lamp 5200 itself according to a surrounding environment or situation. Additionally, the devices 5300 to 5800 included in the network system 500 may be controlled using Li-Fi communications using visible light emitted from the LED lamp 5200, for example.

The LED lamp 5200 may automatically adjust illumination of the LED lamp 5200 on the basis of information of a surrounding environment transmitted from the gateway 5100 through the communications module 5210 for a lamp or information of a surrounding environment collected from a sensor installed in the LED lamp 5200. For example, brightness of illumination of the LED lamp 5200 may be automatically adjusted according to types of programs broadcast on the television 5310 or brightness of a screen. To this end, the LED lamp 5200 may receive operation information of the TV 5310 from the communications module 5210 for a lamp connected to the gateway 5100. The communications module 5210 for a lamp may be integrally modularized with a sensor and/or a controller included in the LED lamp 5200.

For example, in an example embodiment in which a program broadcast on a TV is a drama, a color temperature of illumination may be decreased to be 12000K or lower, for example, to 5000K, and a color tone may be adjusted according to preset values, to present a cozy atmosphere. Conversely, when a program is a comedy, the network system 5000 may be configured so that a color temperature of illumination is increased to 5000K or higher according to a preset value and illumination may be adjusted to white illumination based on a blue color.

Additionally, in an example embodiment in which no one is at home, when a predetermined time has lapsed after a digital door lock 5400 is locked, all of the turned-on LED lamps 5200 may be turned off to prevent a waste of electricity. In an example embodiment in which a security mode is set through the mobile device 5800, or the like, when the digital door lock 5400 is locked with no person in a home, the LED lamp 5200 may be maintained in a turned-on state.

In example embodiments, operation of the LED lamp 5200 may be controlled according to surrounding environments collected through various sensors connected to the network system 5000. For example, in a case in which the network system 5000 is realized in a building, lighting, a position sensor, and a communications module are combined in the building, and position information of people in the building is collected and lighting is turned on or turned off, or the collected information may be provided in real time to effectively manage facilities or effectively utilized idle space. In general, a lighting device such as the LED lamp 5200 may be disposed in almost every space of each floor of a building, and thus, various types of information of the building may be collected through a sensor integrally provided with the LED lamp 5200 and used for managing facilities and utilizing idle space.

The LED lamp 5200 may be combined with an image sensor, a storage device, and the communications module 5210 for a lamp, to be utilized as a device for maintaining building security or to sense and cope with an emergency situation. For example, in an example embodiment in which a smoke or temperature sensor, or the like, is attached to the LED lamp 5200, a fire may be promptly sensed and damage may be minimized sounding an alarm or otherwise alerting emergency workers, such as fire officials, for example. Additionally, brightness of lighting may be adjusted in consideration of outside weather or an amount of sunshine, thereby saving energy and providing an agreeable illumination environment.

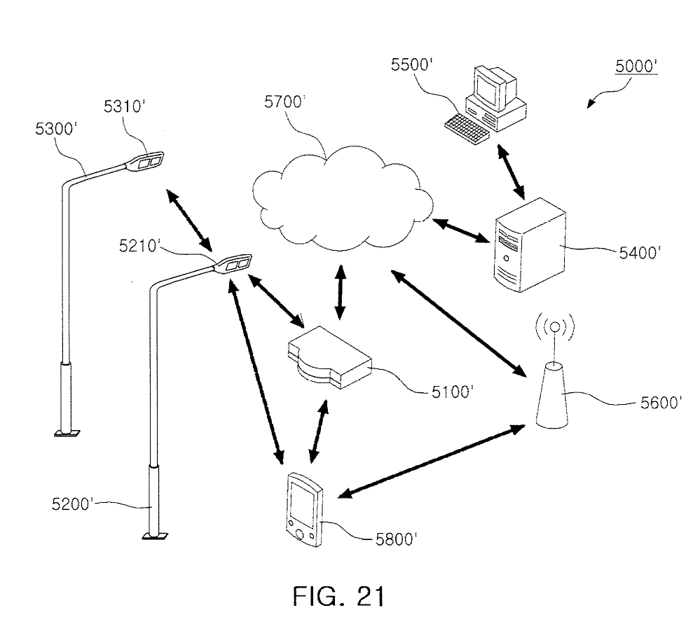

As described above, the network system 5000 may also be applied to an open space such as a street or a park, as well as to a closed space such as a house, an office, or a building. In an example embodiment in which the network system 5000 is intended to be applied to an open space without physical limitation, it may be difficult to realize the network system 5000 due to a limitation in a distance of wireless communications, and communications interference due to various obstacles. In such embodiments, a sensor, a communications module, and the like, may be installed in each lighting fixture, and each lighting fixture may be used as a means of collecting information or a means of relaying communications, whereby the network system 5000 may be more effectively realized in an open environment. This will be described in greater detail in the discussion related to FIG. 21 hereinafter.

FIG. 21 is a view illustrating an example embodiment of a network system 5000′ applied to an open space. Referring to FIG. 21, a network system 5000′ according to example embodiments in accordance with principles of inventive concepts may include a communications connection device 5100′, a plurality of lighting fixtures 5200′ and 5300′ installed at every predetermined interval and connected to be available for communicating with the communications connection device 5100′, a server 5400′, a computer 5500′ managing the server 5400′, a communications base station 5600′, a communications network 5700′, a mobile device 5800′, and the like.

Each of the plurality of lighting fixtures 5200′ and 5300′ installed in an open outer space such as a street or a park may include smart engines 5210′ and 5310′, respectively. The smart engines 5210′ and 5310′ may include a light emitting device in accordance with principles of inventive concepts emitting light, a driver driving the light emitting device, a sensor collecting information of a surrounding environment, a communications module, and the like. The smart engines 5210′ and 5310′ may communicate with other neighboring equipment by means of the communications module according to communications protocols such as Wi-Fi, ZigBee, and Li-Fi.

For example, one smart engine 5210′ may be connected to communicate with another smart engine 5310′. In example embodiments in accordance with principles of inventive concepts, a Wi-Fi extending technique (Wi-Fi mesh) may be applied to communications between the smart engines 5210′ and 5310′. The at least one smart engine 5210′ may be connected to the communication connection device 5100′ connected to the communications network 5700′ by wired/wireless communications. In order to increase communication efficiency, some smart engines 5210′ and 5310′ may be grouped and connected to the single communications connection device 5100′.

In example embodiments, communications connection device 5100′ may be an access point (AP) available for wired/wireless communications, which may relay communications between the communications network 5700′ and other equipment. The communications connection device 5100′ may be connected to the communications network 5700′ in either a wired manner or a wireless manner, and for example, the communications connection device 5100′ may be mechanically received in any one of the lighting fixtures 5200′ and 5300′.

The communications connection device 5100′ may be connected to the mobile device 5800′ through a communication protocol such as Wi-Fi, or the like. A user of the mobile device 5800′ may receive surrounding environment information collected by the plurality of smart engines 5210′ and 5310′ through the communications connection device 5100′ connected to the smart engine 5210′ of the lighting fixture 5200′ adjacent to the mobile device 5800′. In example embodiments in accordance with principles of inventive concepts, surrounding environment information may include nearby traffic information, weather information, and the like. The mobile device 5800′ may be connected to the communications network 5700′ according to a wireless cellular communications scheme such as 3G or 4G through the communications base station 5600′.

The server 5400′ connected to the communications network 5700′ may receive information collected by the smart engines 5210′ and 5310′ respectively installed in the lighting fixtures 5200′ and 5300′ and may monitor an operational state, or the like, of each of the lighting fixtures 5200′ and 5300′. In order to manage the lighting fixtures 5200′ and 5300′ on the basis of the monitoring results of the operational states of the lighting fixtures 5200′ and 5300′, the server 5400′ may be connected to the computer 5500′ providing a management system, for example. In example embodiments in accordance with principles of inventive concepts, computer 5500′ may execute software, or the like, capable of monitoring and managing operational states of the lighting fixtures 5200′ and 5300′, specifically, the smart engines 5210′ and 5310′.

As set forth above, according to example embodiments in accordance with principles of inventive concepts, an amount of light of the LED package may be increased and manufacturing costs thereof may be reduced.

While example embodiments have been shown and described above, it will be apparent to those skilled in the art that modifications and variations could be made without departing from the scope of the inventive concepts as defined by the appended claims.

What is claimed is:

1. A light emitting diode (LED) package comprising:
a package board having a first surface having a plurality of chip mounting regions and a second surface opposing the first surface, and including a plurality of first and second through electrodes electrically connecting the first surface and the second surface and disposed in the plurality of chip mounting regions;
a plurality of integral LED chips disposed in the plurality of chip mounting regions of the first surface of the package board and each having one surface on which first and second electrodes are disposed, wherein the first and second electrodes are connected to the first and second through electrodes positioned in the chip mounting regions; and
a connection electrode disposed on at least one of the first surface and the second surface of the package board, and connecting the first and second through electrodes of adjacent chip mounting regions so that the plurality of integral LED chips are connected.

2. The LED package of claim 1, further comprising first and second pad electrodes disposed on the second surface of the package board and covering at least one first and second through electrodes.

3. The LED package of claim 2, wherein the first and second pad electrodes and the connection electrode substantially have the same thickness and are formed of a material having the same composition.

4. The LED package of claim 1, further comprising an encapsulant disposed on the first surface of the package board to cover the plurality of LED chips.

5. The LED package of claim 1, wherein
the plurality of LED chips each include a light emitting structure formed by stacking a first conductivity-type semiconductor layer, an active layer, and a second conductivity-type semiconductor layer, and the second conductivity-type semiconductor layer provides the one surface on which the first and second electrodes are disposed, and
the first electrode includes one or more conductive vias electrically insulated from the second conductivity-type semiconductor layer and the active layer and extending to a region of the first conductivity-type semiconductor layer.

6. The LED package of claim 1, wherein the plurality of LED chips are arranged in a plurality of rows and a plurality of columns on the first surface of the package board.

7. The LED package of claim 6, wherein LED chips arranged in the same column, among the plurality of LED chips, are connected in series.

8. The LED package of claim 6, wherein LED chips arranged in the same row, among the plurality of LED chips, are connected in parallel.

9. The LED package of claim 1, further comprising a heat sink attached to the second surface of the package board.

10. The LED package of claim 9, further comprising an insulating layer disposed between the heat sink and the package board.

11. The LED package of claim 9, wherein
a circuit board is disposed in a partial region of a region in which the heat sink and the package board are in contact, and
the circuit board is electrically connected to at least two of the plurality of LED chips.

12. The LED package of claim 1, wherein the package board includes a molding unit surrounding the plurality of first and second through electrodes.

13. A light emitting diode (LED) package comprising:
a package board having a first surface and a second surface opposing the first surface;
a plurality of first and second through electrodes penetrating through the package board in a thickness direction; and
a plurality of integral LED chips electrically connected to the plurality of first and second through electrodes and mounted on the first surface of the package board,
wherein at least one of the first and second through electrodes electrically connected to any one of the plurality of LED chips is electrically connected to any one of first and second through electrodes electrically connected to an LED chip adjacent thereto.

14. The LED package of claim 13, wherein at least one of the first and second through electrodes electrically connected to any one of the plurality of LED chips and the any one of the first and second through electrodes electrically connected to the LED chip adjacent thereto are electrically connected by the connection electrode disposed on the second surface of the package board.

15. A light emitting diode (LED) package comprising:
a package board having a first surface and a second surface opposing the first surface;
a plurality of first and second through electrodes penetrating through the package board in a thickness direction;
a plurality of integral LED chips mounted on the first surface of the package board and electrically connected to the plurality of first and second through electrodes; and
a connection electrode disposed on at least one surface of the package board and extending from the plurality of first and second through electrodes to connect adjacent LED chips.

16. The LED package of claim 15, further comprising a wavelength conversion unit to convert the wavelength of light emitted by an LED chip.

17. The LED package of claim 16, further comprising a heat sink attached to the second surface of the package board.

18. The LED package of claim 16, further comprising an insulating layer disposed between the heat sink and the package board.

19. The LED package of claim 17, wherein
a circuit board is disposed in a partial region of a region in which the heat sink and the package board are in contact, and
the circuit board is electrically connected to supply power to all the LED chips without direct connection to all of them.

20. The LED package of claim 15, wherein the package board includes a molding unit surrounding the plurality of first and second through electrodes.
